(19) United States
(12) Patent Application Publication
(10) Pub. No.: US 2006/0232171 A1
(43) Pub. Date: Oct. 19, 2006

(54) PIEZOELECTRIC DIAPHRAGM ASSEMBLY WITH CONDUCTORS ON FLEXIBLE FILM

(75) Inventor: Bruce E. TIETZE, Seaford, VA (US)

Correspondence Address: NIXON & VANDERHYE, PC, 901 NORTH GLEBE ROAD, 11TH FLOOR, ARLINGTON, VA, 22203, US

(73) Assignee: PAR Technologies, LLC, Hampton, VA (US)

(21) Appl. No.: 11/279,647

(22) Filed: Apr. 13, 2006

Related U.S. Application Data
(60) Provisional application No. 60/670,692, filed on Apr. 13, 2005.
(60) Provisional application No. 60/670,657, filed on Apr. 13, 2005.

(51) Int. Cl. H01L 41/00; H04R 17/00

(52) U.S. Cl. 310/365; 29/25.35; 29/831; 310/311

(57) ABSTRACT

A laminated piezoelectric composite comprises a metallic substrate (20); a piezoelectric wafer (32) having a first surface and a second surface; a first adhesive carrier layer (100) between the first surface of the piezoelectric wafer (32) and the substrate (22); a first conductive lead (110) carried by the first adhesive carrier layer (100) and connected to a first surface of the piezoelectric wafer (32); and, a second conductive lead (100′) connected to the second surface of the piezoelectric wafer (32). The first adhesive carrier layer (100) serves both to adhere the first surface of the piezoelectric wafer (32) to the substrate (22) and to carry a first conductive lead (110) for supplying an electrical signal or voltage to the first surface of the piezoelectric wafer (32). The second conductive lead (110′) supplies an electrical signal or voltage to the second surface of the piezoelectric wafer (32). The first adhesive carrier layer can comprise a high dielectric soluble aromatic polyimide film. In a variant example embodiment, the laminated piezoelectric composite further comprises a second adhesive carrier layer (100′) which serves to carry the second conductive lead (110′). When the laminated piezoelectric composite further comprises a cover layer (48) placed on top of the piezoelectric wafer (32), the second adhesive carrier layer (100′) can also serve to adhere the cover layer (48) to the second surface of the piezoelectric wafer (32).

### BACKGROUND

This application claims the priority and benefit of the following United States Provisional Patent Applications, both of which are incorporated by reference herein in their entirety: U.S. Provisional Patent Application 60/670,692, filed Apr. 13, 2005, entitled PIEZOELECTRIC DIAPHRAGM ASSEMBLY WITH CONDUCTORS ON FLEXIBLE FILM, and U.S. Provisional Patent Application 60/670,657, filed Apr. 13, 2005, entitled PIEZOELECTRIC DIAPHRAGM ASSEMBLIES AND METHODS OF MAKING SAME.

### FIELD OF THE INVENTION

The present invention pertains to piezoelectric diaphragm assemblies and laminated piezoelectric composites, and methods of making the same.

### RELATED ART AND OTHER CONSIDERATIONS

Piezoelectric materials can be defined by demonstration of the direct piezoelectric effect, which is the ability to polarize under an applied strain. The corollary to this effect is the inverse piezoelectric effect, which is a material's ability to strain under an applied electric field. This physical response to a stimulus is rooted in the displacement of ionic charges within a crystal structure. The PZT (lead zirconate titanate) component is a piezoelectric material, as this class of materials exhibits the piezoelectric effect. Most commercially available PZT materials are polycrystalline, and therefore the displacement of ionic charges takes place in domains where all polarization vectors are aligned. These domains are initially oriented through application of a strong DC field (“poling”), which only partially aligns the dipoles due to their polycrystalline nature. Complete domain alignment is theoretically possible in single crystal PZTs.

Examples of pumps with piezoelectric diaphragms are shown in PCT Patent Application PCT/US01/28947, filed 14 Sep. 2001; U.S. patent application Ser. No. 10/380,547, filed Mar. 17, 2003, entitled “Piezoelectric Actuator and Pump Using Same”; U.S. patent application Ser. No. 10/380,589, filed Mar. 17, 2003, entitled “Piezoelectric Actuator and Pump Using Same”, all of which are incorporated herein by reference.

Examples of flexible circuits and the like are illustrated in one or more of the following United States Patents: U.S. Pat. No. 6,781,285; U.S. Pat. No. 6,420,819; U.S. Pat. No. 6,404,107; U.S. Pat. No. 6,069,433; U.S. Pat. No. 5,687,462; and, U.S. Pat. No. 5,656,882.

### BRIEF SUMMARY

A laminated piezoelectric composite comprises a metallic substrate; a piezoelectric wafer having a first surface and a second surface; a first adhesive carrier layer between the first surface of the piezoelectric wafer and the substrate; a first conductive lead carried by the first adhesive carrier layer and connected to a first surface of the piezoelectric wafer; and, a second conductive lead connected to the second surface of the piezoelectric wafer. The first adhesive carrier layer serves both to adhere the first surface of the piezoelectric wafer to the substrate and to carry a first conductive lead for supplying an electrical signal or voltage to the first surface of the piezoelectric wafer. The second conductive lead supplies an electrical signal or voltage to the second surface of the piezoelectric wafer.

In an example, non-limiting embodiment, the first adhesive carrier layer comprises a high dielectric soluble aromatic polyimide film.

In a variant example embodiment, the laminated piezoelectric composite further comprises a second adhesive carrier layer which serves to carry the second conductive lead. When the laminated piezoelectric composite further comprises a cover layer placed on top of the piezoelectric wafer, the second adhesive carrier layer can also serve to adhere the cover layer to the second surface of the piezoelectric wafer.

In embodiments having both a first adhesive carrier layer and a second adhesive carrier layer, each of the first adhesive carrier layer and the second adhesive carrier layer have an appendage which extends in an extension direction beyond a footprint of the substrate. The respective appendices of the first adhesive carrier layer and the second adhesive carrier layer are overlaid and fused or adhered together to form a fused multilayer conductor carrier. Preferably, in a thickness direction of the fused multilayer conductor carrier the first conductive lead does not overlap the second conductive lead. Moreover, in the thickness direction the appendage of the first adhesive carrier layer at least partially covers or encloses the second conductive lead and the appendage of the second adhesive carrier layer at least partially covers or encloses the first conductive lead.

As another optional feature, the appendage of the first adhesive carrier layer can be configured to form a first relief and the appendage of the second adhesive carrier layer can be configured to form a second relief. A distal end of the first conductor is exposed by the second relief and a distal end of the second conductor is exposed by the first relief.

The first conductive lead and the second conductive lead can be screened or deposited on the first adhesive carrier layer and the second adhesive carrier layer respectively. The first conductive lead and the second conductive lead preferably comprise silver, e.g., silver impregnated ink, or another conductive substance chosen to be thin (so as not to result in stress concentrations that may crack the piezoelectric wafer and/or dampen the amount of displacement experience by the stack during activation) and easily selectively applied.

Another aspect of the technology concerns a method of making a laminated piezoelectric composite, the laminated piezoelectric composite comprising at least a substrate and a piezoelectric wafer. Basic steps of the method comprise forming a first conductive lead on a first adhesive carrier layer; inserting the first adhesive carrier layer between a first surface of the piezoelectric wafer and the substrate; using the first adhesive carrier layer to adhere the first surface of the piezoelectric wafer to the substrate and to carry the first conductive lead for supplying an electrical signal or voltage to the first surface of the piezoelectric wafer. As optional step can include plasticizing the first adhesive carrier layer to adhere the first surface of the piezoelectric wafer to the substrate.

### BRIEF DESCRIPTION OF THE DRAWINGS

The foregoing and other objects, features, and advantages of the invention will be apparent from the following more particular description of preferred embodiments as illustrated in the accompanying drawings in which reference characters refer to the same parts throughout the various views. The drawings are not necessarily to scale, emphasis instead being placed upon illustrating the principles of the invention.

FIG. 1 is a side cross section view of an example, representative, non-limiting embodiment of a laminated piezoelectric composite.

FIG. 2 is a plan view of the composite of FIG. 1.

FIG. 3A is a plan view of a first example implementation of a adhesive carrier layer suitable for making a laminated piezoelectric composite according to the second mode of the piezoelectric fabrication technology.

FIG. 3B is a side view of the example adhesive carrier layer of FIG. 3A.

FIG. 3C is an end view of the example adhesive carrier layer of FIG. 3A.

FIG. 4A is a plan view of a first adhesive carrier layer which is oriented with its conductive lead positioned upward to face a piezoelectric wafer.

FIG. 4B is a plan view of a second adhesive carrier layer which is oriented with its conductive lead positioned downward to face a piezoelectric wafer.

FIG. 5 is a schematic end view showing how a first adhesive carrier layer and a second adhesive carrier layer are oriented with their respective conductive leads oriented toward one another.

FIG. 6 is an end schematic view showing exposed distal connector ends of two adhesive carrier layers engaged by a side-by-side dual contact connector.

FIG. 7A is a plan view of a second example implementation of a adhesive carrier layer suitable for making a laminated piezoelectric composite according to the second mode of the piezoelectric fabrication technology.

FIG. 7B is a side view of the example adhesive carrier layer of FIG. 7A.

FIG. 7C is an end view of the example adhesive carrier layer of FIG. 7A.

FIG. 8A is a plan view of a third example implementation of a adhesive carrier layer suitable for making a laminated piezoelectric composite according to the second mode of the piezoelectric fabrication technology.

FIG. 8B is a side view of the example adhesive carrier layer of FIG. 8A.

FIG. 8C is an end view of the example adhesive carrier layer of FIG. 8A.

FIG. 9A-FIG. 9J are side cross section views of basic, example steps involved in a process of making a laminated piezoelectric composite according to an example mode of piezoelectric fabrication technology.

FIG. 10A-FIG. 10J are plan views showing the basic, example steps of FIG. 9A-FIG. 9J, respectively.

### DETAILED DESCRIPTION OF THE DRAWINGS

In the following description, for purposes of explanation and not limitation, specific details are set forth such as particular architectures, interfaces, techniques, etc. in order to provide a thorough understanding of the present invention. However, it will be apparent to those skilled in the art that the present invention may be practiced in other embodiments that depart from these specific details. In other instances, detailed descriptions of well-known devices, circuits, and methods are omitted so as not to obscure the description of the present invention with unnecessary detail.

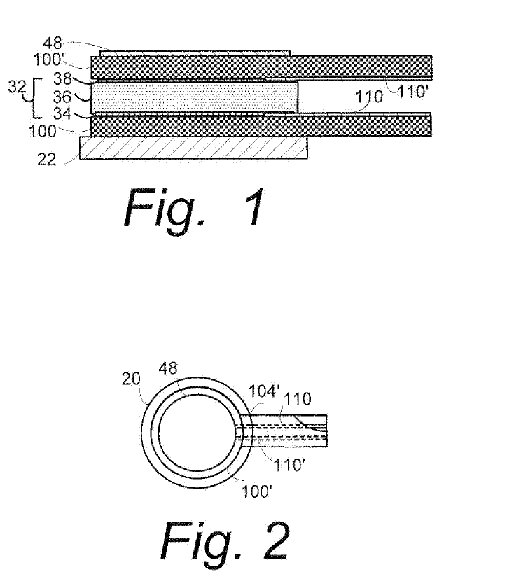

FIG. 1 and FIG. 2 show an example, representative, non-limiting embodiment of a laminated piezoelectric composite 20. The laminated piezoelectric composite 20 is also referred to as a multilayer stack. In the illustrated example implementation, the laminated piezoelectric composite 20 and its constituent layers have an essentially circular shape, although in other implementations other shapes and/or configurations are possible.

The laminated piezoelectric composite 20 comprises (in ascending order) a substrate 22; a first adhesive carrier layer 100; piezoelectric wafer 32; second adhesive carrier layer 100′; and, an optional cover layer 48.

In some but not all embodiments, various layers of the laminated piezoelectric composite 20 have different surface areas or diameters so as to give the laminated piezoelectric composite a side appearance resembling a wedding cake. For example, in the modes which happen to be illustrated herein a substrate layer has a larger diameter than a piezoelectric wafer layer which is over the substrate layer, and in embodiments which have a cover layer the piezoelectric wafer layer has a larger diameter than the cover layer. This wedding cake or indented layer configuration has various advantages, including but not limited to the fact that the substrate layer may be more easily grasped or retained into an incorporating structure such as a pump body, for example.

The substrate 22 is preferably an electrically conductive metal. For example, substrate 22 can be a stainless steel disk of about 0.1 mm thickness. The diameter of substrate can preferably range from about 20 mm to about 25 mm, but can be as small as approximately 5 mm and as large as approximately 40 mm.

The adhesive carrier layers 100 and 100′ are both preferably on the order of about 25 μm thick and have formed thereon conductor leads 110 and 110′, respectively, as hereinafter described.

The piezoelectric wafer 32 is a type that has a piezoelectric (ceramic) core 36 which bears a piezoelectric wafer first electrode 34 on a first side of core 36 and a piezoelectric wafer second electrode 38 on a second side of core 36. The piezoelectric wafer first electrode 34 and piezoelectric wafer second electrode 38 have circumferences which are slightly recessed from the edge of piezoelectric core 36, e.g., the diameters of piezoelectric wafer first electrode 34 and piezoelectric wafer second electrode 38 are preferably slightly smaller than the diameter of piezoelectric core 36.

Preferably the cover layer 48, when used, is a metallic conductor layer, such as aluminum, for example. In the illustrated embodiment, cover layer 48 has a thickness of about 0.05 mm. In embodiments in which cover layer 48 is utilized, preferably a ratio of thickness of cover layer 48 to substrate 22 is on the order of about 1:4, and a ratio of elastic modulus of cover layer 48 to substrate 22 is on the order of 1:3.

The layers of laminated piezoelectric composite 20 can be assembled in various ways. For example, the multilayer stack described above can be treated under pressure and temperature to bond the layers into the laminated piezoelectric composite. The bonding can occur in various ways, such as (for example) using an adhesive or plasticizing the adhesive carrier layers.

Various types of materials can be used for the adhesive carrier layers 100, 100′, such as certain polyimide films, for example. In this regard, plasticization can occur when using certain polyimide films, such as (for example) the types of film typified by the LaRC™-SI film (or equivalent) developed by NASA Langley Research Center and described, e.g., in one or more of the following: (1) Bryant, R. G., “LaRC™-SI: A Soluble Aromatic Polyimide,” High Performance Polymers, Vol. 8, No. 4, pp. 607-615 (1996); (2) Whitley, K. S., et al., “Mechanical Properties of LaRC™-SI Polymer For A Range of Molecular Weights,”, NASA/TM-2000-210304; and (3) U.S. Pat. No. 5,741,883. LaRC™-SI film is noted for its initial solubility in high-boiling aprotic solvents.

The substrate 22 and the optional cover layer 48 are preferably chosen of materials which have a different coefficient of thermal expansion whereby, during cooling after the heat and pressure treating process, the laminated piezoelectric member has a slightly domed configuration. Thus, thermal expansion mismatches between the substrate 22 and the piezoelectric wafer upon cooling creates a dome or “crown” to the device. However, device actuation does not depend upon or require the presence of domed geometry, as flat laminated piezoelectric composites are also within the ambit of this technology.

The adhesive carrier layers 100 and 100′ thus serve for adhering layers of the composite, e.g., adhering the piezoelectric wafer 32 to substrate 22 and, when a cover layer 48 is used, for adhering cover layer 48 to piezoelectric wafer 32. As such, the adhesive carrier layers 100 and 100′ must have sufficient bonding or adhesive properties for forming a composite having these constituent layers, or be treatable to provide such bonding or adhesive properties.

The adhesive carrier layers 100 and 100′ not only serve for adhering the layers of the composite, but also serve a dual purpose in carrying conductive leads 110 and 110′. The conductive leads 110 and 110′ can be screened or deposited or otherwise formed on adhesive carrier layers 100 and 100′. Since they carry conductive leads, the adhesive carrier layers 100 and 100′ should be formed from an insulator material. The aforementioned polyimide film(s) is an example of a insulative material that can be used for adhesive carrier layers 100 and 100′.

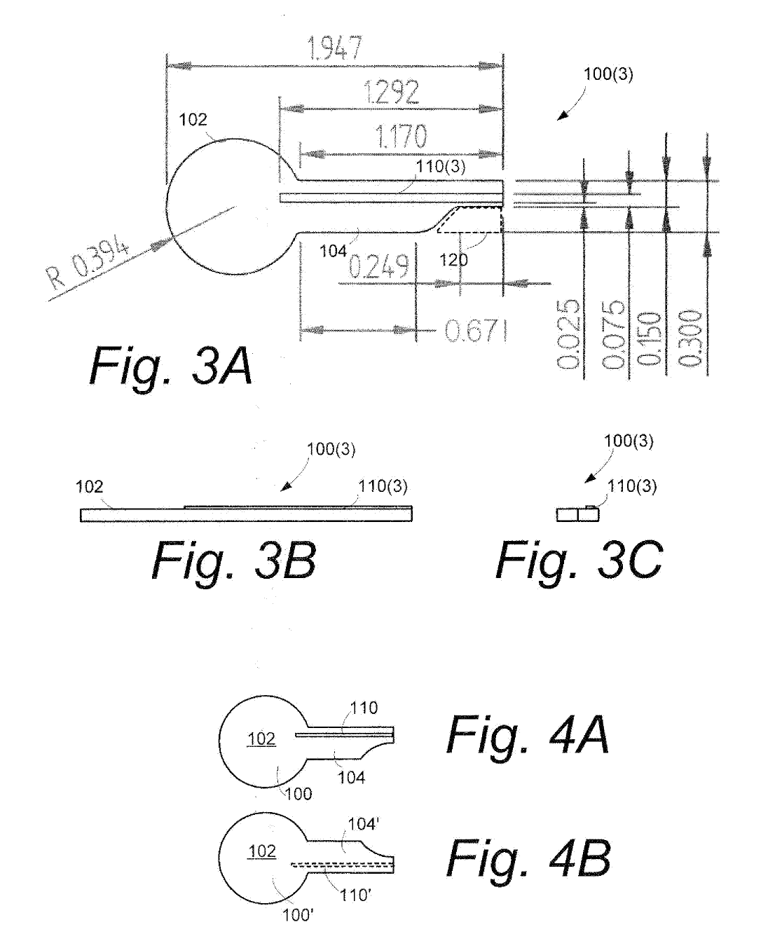

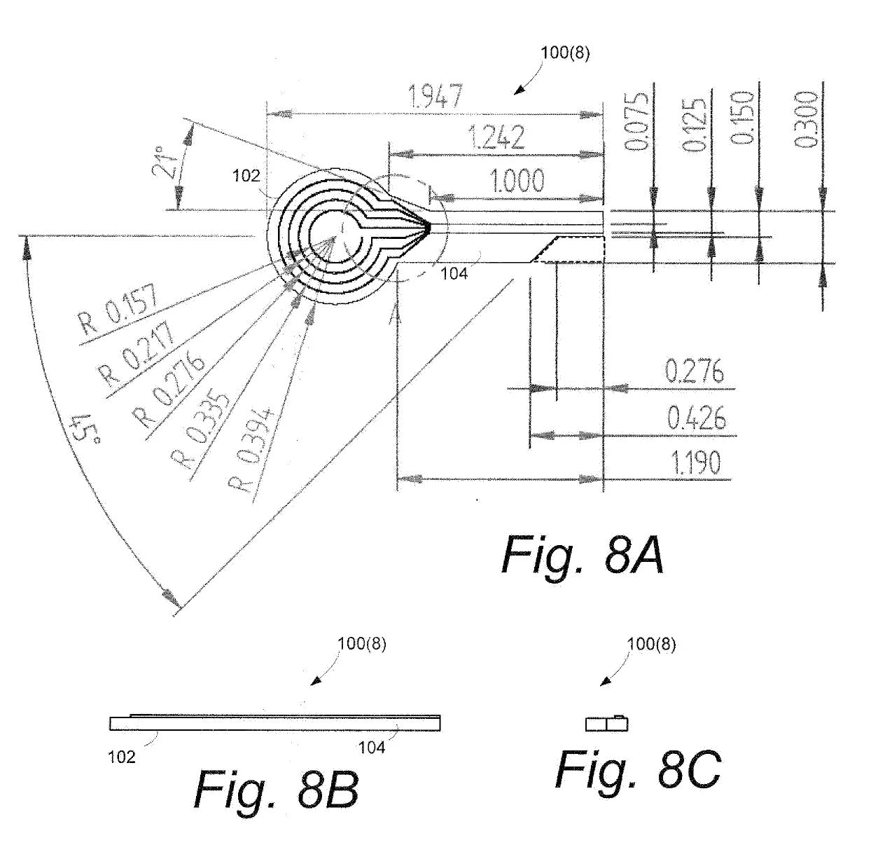

The adhesive carrier layers 100 and 100′ can have several implementations, a first such example implementation being shown as adhesive carrier layer 100(3) in FIG. 3A-FIG. 3C; a second such example implementation being shown as adhesive carrier layer 100(7) in FIG. 7A-FIG. 7C; and, a third such example implementation being shown as adhesive carrier layer 100(8) in FIG. 8A-FIG. 8C. Other example implementations are also possible. In the drawings, the dimensions (which are non-limiting and provided only as an example) provided are in the English system (e.g., inches) rather than metric.

Herein, for simplicity, when generically describing the adhesive carrier layer of the illustrated or other implementations, reference will simply be made to adhesive carrier layer 100. Comparable features of the adhesive carrier layers bear the same reference numerals from implementation to implementation unless otherwise noted. It so happens that, for the example implementations herein illustrated, the overall shape of the adhesive carrier layer 100 is substantially the same.

As illustrated in the first implementation of FIG. 3A, adhesive carrier layer 100(3) has a stack region or portion 102 which, in the illustrated embodiment of a circular stack, is essentially circular. The adhesive carrier layer 100(3) also has an appendage 104 which extends beyond a footprint of the substrate 22. The appendage 104 extends away from stack portion 102 in an extension direction. For the circular implementation, the extension direction is essentially the radial direction of the stack and lies in the plane of the adhesive carrier 100. The exact shape of the appendage 104 may vary from implementation to implementation.

In each implementation, the adhesive carrier layer 100 carries a conductive lead. The conductive lead can be formed on adhesive carrier layer 100 by any suitable technique, such as deposition, photolithography, or screening, for example. The conductive lead is preferably formed of a metal, e.g., silver or copper, and preferably silver. The shape of the conductive lead and/or its path of travel on adhesive carrier layer 100 can vary from implementation to implementation, as illustrated by the three differing implementations herein illustrated by way of example.

In particular, in the first implementation of FIG. 3A-FIG. 3C, conductive lead 110(3) is essentially rectangular and extends linearly along appendage 104. A first end of conductive lead 110(3) terminates just within the periphery of the stack of the laminated piezoelectric composite, e.g., sufficiently interior of the stack (e.g., 3.5 mm into the disc surface) to make contact with the electrodes of the piezoelectric wafer.

In the second implementation of FIG. 7A-FIG. 7C, conductive lead 110(7) of adhesive carrier layer 100(7) has an essentially rectangular segment that extends linearly along appendage 104. A first end of the rectangular linear segment is positioned just within the periphery of the stack of the laminated piezoelectric composite. In addition, at its first end of its rectangular linear segment, conductive lead 110(7) branches into two semicircular segments 112(7) and 114(7). The two semicircular segments 112(7) and 114(7) form a recessed semicircle around almost three quarters of the stack, the semicircle formed by segments 1112(7) and 114(7) being recessed with respect to a perimeter of the stack portion of film layer 100(7). The recess of the two semicircular segments 112(7) and 114(7) bring the two semicircular segments 112(7) and 114(7) into contact with the surface electrodes of the piezoelectric wafer 32.

In the third implementation of FIG. 8A-FIG. 8C, conductive lead 110(8) of adhesive carrier layer 100(8) also has an essentially rectangular segment that extends linearly along appendage 104. As in the previously described implementations, a first end of the rectangular linear segment is positioned just within the periphery of the stack of the laminated piezoelectric composite. In addition, at its first end of its rectangular linear segment, conductive lead 110(8) branches or divides into numerous essentially nested segments. All but an inner central nested segment have two angled or tapered diverging regions which connect to the rectangular linear segment; two linear spacer regions which are contiguous with the respective diverging regions and which extend parallel to the rectangular linear segment; and, a semi-circular region in the stack area of the laminated piezoelectric composite which is contiguous with the spacer region. The inner nested segment has a semi-circular region which connects via a single linear spacer region to the first send of the rectangular linear segment of conductive lead 110(8). The semi-circular regions of the nested segments of the conductive lead 110(8) are preferably concentric. In the illustrated implementation, four such nested segments are shown for conductive lead 110(8). It will be appreciated that a lesser or greater number can be provided in other implementations, and that other geometries are also possible for the nested segments.

In the illustrated implementations, the conductive leads 110 are generally off-center on the appendage 104 with respect to a transverse direction of the appendage 104. The transverse direction of each appendage 104 lies in the plane of the adhesive carrier and is perpendicular to the extension direction of the appendage 104. Moreover, in some variations of the example implementations, an end of an edge of appendage 104 tapers or otherwise is inclined toward a centerline of the appendage in the extension direction. Thusly tapered, a distal or second end of the appendage 104 vacates a relief region 120 which is framed by broken lines (see, e.g., FIG. 3A). By vacating the relief region 120, the appendage 104 is non-symmetrical about its centerline in the extension direction. As explained hereinafter, this non-symmetry on the appendage of one adhesive carrier layer of the stack facilitates exposure of an oppositely-facing conductor on an appendage of another adhesive carrier layer of the stack.

The adhesive carrier layer 100 is oriented with its conductive lead 110 positioned upward to face the piezoelectric wafer 32 and to contact at least a portion of the piezoelectric wafer first electrode 34. The second adhesive carrier layer 100′ is oriented with its conductive lead 110′ positioned downward to face the piezoelectric wafer 32. At least a portion (e.g., the first end) of the conductive lead 110′ contacts the piezoelectric wafer second electrode 38.

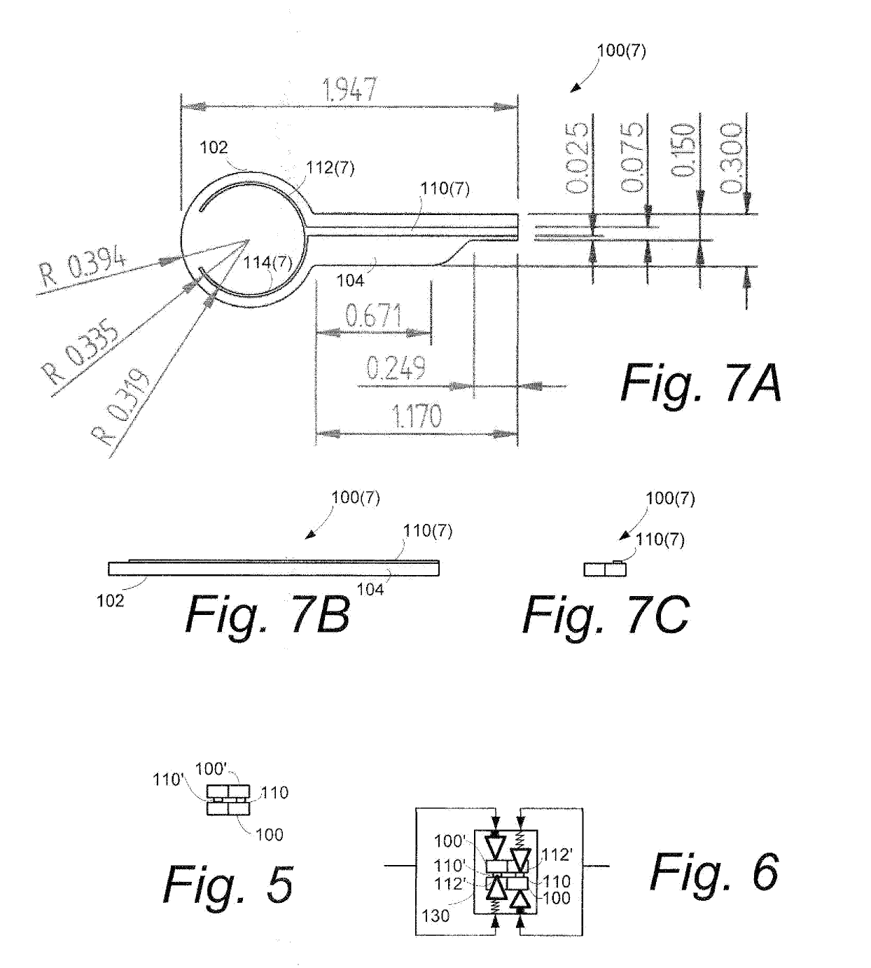

In essence, the first adhesive carrier layer 100 and the second adhesive carrier layer 100′ are identical, but are positioned differently along the extension direction. In fact, the second adhesive carrier layer 100′ is positioned to be a mirror image of the first adhesive carrier layer 100 with respect to the extension direction. FIG. 5 illustrates how the first adhesive carrier layer 100 positioned in FIG. 3C and how the second adhesive carrier layer 100′ positioned in FIG. 3C are oriented with their respective conductive leads 110 and 110′ oriented toward one another, e.g., facing one another. In particular, the conductive lead 110 of the first adhesive carrier layer 100 faces upward, while the conductive lead 110′ of the second adhesive carrier layer 100′ faces downward.

The first adhesive carrier layer 100 and the second adhesive carrier layer 100′ are preferably fused or bonded together to form a fused multilayer conductor carrier. The fusing or bonding operation is perferably the same operation in which the piezoelectric wafer 32 is bonded or adhered to substrate 22 by the adhesive carrier layer 100 and in which the cover layer 48 (when used) is bonded or adhered to the piezoelectric wafer 32 by the second adhesive carrier layer 100′. When the first adhesive carrier layer 100 and second adhesive carrier layer 100′ are bonded or adhered together, the conductors 110 and 110′ carried thereon are essentially enveloped or enclosed (at least partially) by the oppositely facing adhesive carrier layer.

Thus, the respective appendices of the first adhesive carrier layer and the second adhesive carrier layer can be overlaid and fused or adhered together to form a fused multilayer conductor carrier. Preferably, in a thickness direction of the fused multilayer conductor carrier the first conductive lead does not overlap the second conductive lead. Moreover, in the thickness direction the appendage of the first adhesive carrier layer at least partially covers or encloses the second conductive lead and the appendage of the second adhesive carrier layer at least partially covers or encloses the first conductive lead.

In embodiments in which it is provided, relief region 120 afforded by the first adhesive carrier layer 100 exposes a second or distal end of the conductive lead 110′ of the second adhesive carrier layer 100′. Similarly, the relief region 120′ afforded by the second adhesive carrier layer 100′ exposes a second or distal end of the conductive lead 110 of the first adhesive carrier layer 100. Thus, as another optional feature, the appendage of the first adhesive carrier layer 100 can be configured to form a first relief 120 and the appendage of the second adhesive carrier layer 100′ can be configured to form a second relief 120′. A distal end of the first conductor 110 is exposed by the second relief 120′ and a distal end of the second conductor 110′ is exposed by the first relief 120.

Advantageously, the distal ends of the two appendages 104 and 104′ can be positioned with their exposed distal connector ends in a side-by-side dual contact connector such as connector 130 shown in FIG. 6. In particular, the relief region 120 enables an upward facing spring-loaded terminal of connector 130 to reach and contact the conductive lead 110′ of second adhesive carrier layer 100′, and likewise the relief region 120′ enables a downward facing spring-loaded terminal of connector 130 to reach and contact the conductive lead 110 of first adhesive carrier layer 100. If desired, a stiffener may be added to bottom ends of each lead to add strength to allow insertion into flat flex connector. Such stiffener may take the form of an additional polyimide layer with an adhesive backer, such as a 6 mil thick polyimide layer with a 2 mil thick adhesive backer.

In other implementations, the relief regions 120 need not be afforded by the adhesive carrier layers, so that their appendages 104 can be essentially symmetrical (e.g., entirely rectangular) rather than having a cutout for allowing the relief region 120. These other implementations are conducive to applications in which the distal ends of the appendages 104 are engaged by a connector which crimps the distal ends for making contact with the respective conductive leads.

Thus, as apparent from the foregoing, in the second mode in a transverse direction perpendicular to the extension direction the first conductive lead 110 does not overlap the second conductive lead 110′, and in the transverse direction the appendage 104 of the first adhesive carrier layer 100 at least partially covers the second conductive lead 110′ and the appendage 104′ of the second adhesive carrier layer 100 at least partially covers the first conductive lead 110. Such coverage provides a two ply or dual layer strength to the two adhesive carrier layers, thereby providing more stability and wear resistance. If desired, the first adhesive carrier layer 100 and the second adhesive carrier layer 100 can be attached together with an adhesive layer, or the first adhesive carrier layer can be topcoated with the second adhesive carrier layer, e.g., screened. In this regard, providing the two adhesive carrier layers with protective covers over the exposed conductive traces can be accomplished in various ways, such as by either attaching a 1 mil adhesive backed polyimide layer each conductive side of the tails or by screening a plastic coating for each conductive side of the tails. The process occurs after the conductive layers have been applied.

The conductive leads 110 formed on the adhesive carrier layers of the second mode are preferably comprised of silver-impregnated ink which is silk-screened on the adhesive carrier layers. Silver is preferred over copper in view of the fact that typically copper is applied with a lamination process or the like and much of the copper must be etched away. Silver-impregnated ink, on the other hand, is thinner and can be selectively applied only where really needed. Moreover, usage of copper as the conductor can result in stress concentrations that may crack the ceramic (piezoelectric wafer) and/or dampen the amount of displacement experience by the stack during activation.

Material selection of cover layer 48 and substrate 22 influences the doming or crowning of the stack via differences in the coefficients of thermal expansion The thickness of each material layer determines the resulting dome height and stress state due to thermal and piezoelectric effects. Preferably a ratio of thickness of the piezoelectric wafer 32 to thickness of the substrate 22 is on the order of 2:1, and more preferably on the order of 1.8:1.0 where the elastic modulus ratio of piezoelectric wafer to substrate is on the order of 0.3:1.0.

The conductive leads of the example laminated piezoelectric composites herein described are connected to a suitable drive circuit. Examples of such drive electronics, including drive circuits for pumps which utilize the laminated piezoelectric composites, are included among those described in U.S. patent application Ser. No. 10/816,000 (attorney docket 4209-26), filed Apr. 2, 2004 by Vogeley et al., entitled “Piezoelectric Devices and Methods and Circuits for Driving Same”, which is incorporated herein by reference in its entirety, or by documents referenced and/or incorporated by reference therein.

As mentioned above, use of cover layer 48 is optional. Such being the case, in an embodiment without cover layer 48 the second conductive lead which carries a signal or voltage to the second surface or second electrode of piezoelectric wafer 32 may be realized in various ways. As a first example, the second surface 38 of piezoelectric wafer 32 could be overlaid by a film or layer similar to that of second adhesive carrier layer 100′, which has the second conductive lead embedded or otherwise carried thereon or therein (but without second adhesive carrier layer 100′ serving to adhere a cover layer such as cover layer 48). As a second example, a conductive lead, wire, or other conductive material, either borne by another layer or film or standing alone, could be soldered or otherwise attached to the second surface 38 of piezoelectric wafer 32 for effecting the electrical contact.

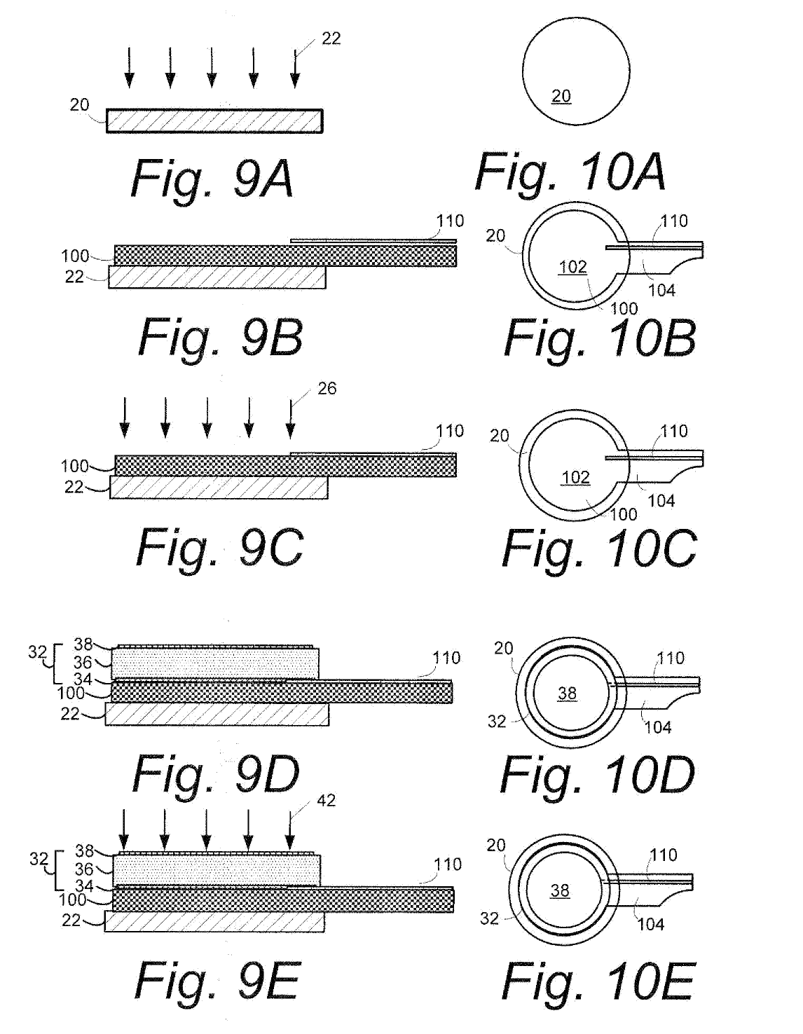

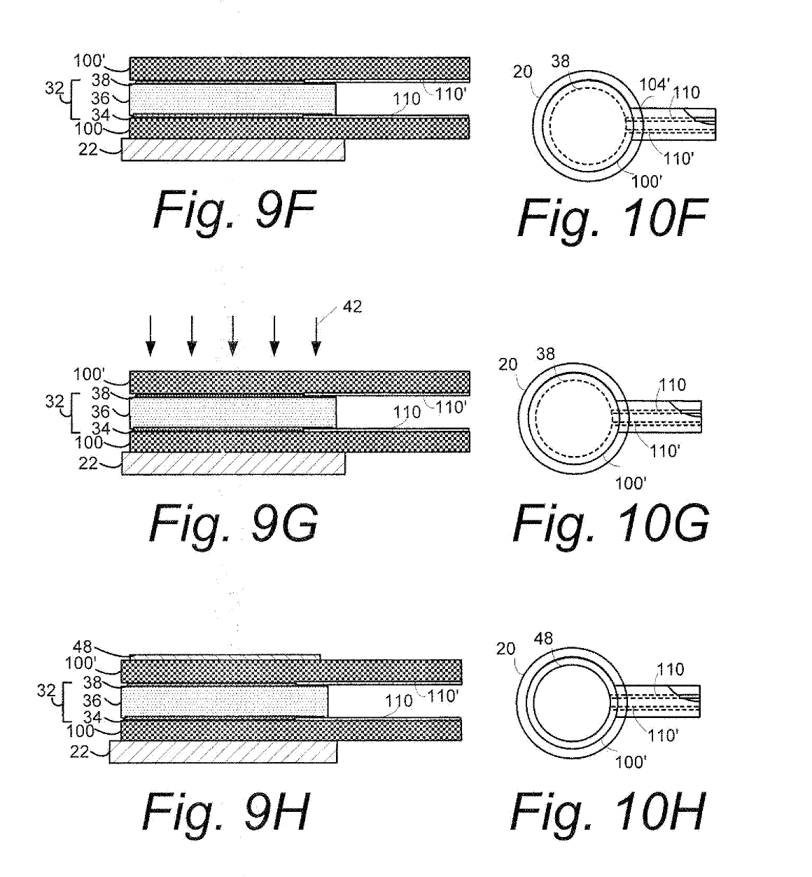

FIG. 9A-FIG. 9J and FIG. 10A-FIG. 10J show basic, example steps involved in a process of making a laminated piezoelectric composite according to an example mode of piezoelectric fabrication technology. FIG. 9A-FIG. 9J show side cross section views of stages of the composition during the respective steps; FIG. 10A-FIG. 10J show plan views. The steps of the process include forming a multilayer stack, and thereafter treating the multilayer stack under pressure and temperature to bond the layers into the laminated piezoelectric member. In the illustrated example, the laminated piezoelectric composite and its constituent layers have an essentially circular shape, although in other implementations other shapes and/or configurations are possible.

A first step illustrated in FIG. 9A and FIG. 10A involves applying (e.g., spraying) a plasticizing solvent to a substrate 20. The application of the plasticizing solvent is depicted by arrows 22. The substrate 20 is preferably an electrically conductive metal. For example, substrate 22 can be a stainless steel disk of about 0.1 mm thickness and having a diameter of approximately 40 mm.

A second step illustrated in FIG. 9B and FIG. 10B involves positioning a adhesive carrier layer 100 over the substrate 22. The adhesive carrier layer 100 is preferably on the order of about 25 μm thick. Again it is to be noted that, in view of the fact that the process ultimately involves heating the multilayer stack so that polyimide films comprising the stack serve to bond the layers of the stack, the plasticizing solvent is therefore chosen as any solvent in which the adhesive carrier layer 100 is soluble, e.g., any solvent which tends to turn the surface of adhesive carrier layer 100 into a gel or render adhesive carrier layer 100 tacky. In so doing, the plasticizing solvent serves, e.g., to facilitate better adhesion of the adhesive carrier layer since, e.g., the gel state of the adhesive carrier layer minimizes air gaps and the like.

The adhesive carrier layer 100 utilized as the second step can be any of the implementations herein described, or other suitable implementations. In the second step of the second mode, the adhesive carrier layer 100 is oriented with its conductive lead 110 positioned upward to face the piezoelectric wafer 32 which will subsequently be positioned thereover.

A third step illustrated in FIG. 9C and FIG. 10C involves applying (e.g., spraying) the plasticizing solvent to adhesive carrier layer 100, as depicted by arrows 26.

A fourth step illustrated in FIG. 9D and FIG. 10D involves positioning a piezoelectric wafer 32 over the adhesive carrier layer 100 so that the end of the first conductive 110 lead contacts a piezoelectric wafer first electrode 34 of the piezoelectric wafer 32. As explained previously, the piezoelectric wafer 32 may be a type that has a piezoelectric (ceramic) core 36 which bears on a piezoelectric wafer first electrode 34 on a first side with and a piezoelectric wafer second electrode 38 on a second side as shown in FIG. 1. If the piezoelectric wafer first electrode 34 and piezoelectric wafer second electrode 38 have circumferences which are slightly recessed from the edge of piezoelectric core 36, the end of the first conductive lead 30 must extend interiorly to reach the electrode.

A fifth step illustrated in FIG. 9E and FIG. 10E involves applying (e.g., spraying) the plasticizing solvent over piezoelectric wafer 32 as depicted by arrows 42.

A sixth step illustrated in FIG. 9F and FIG. 10F involves placing a second adhesive carrier layer 100′ over the piezoelectric wafer layer 32. In the fifth step, the adhesive carrier layer 100′ is oriented with its conductive lead 110′ positioned downward to face the piezoelectric wafer 32 which has already been deposited therebeneath. At least a portion (e.g., the first end) of the conductive lead 110′ contacts the piezoelectric wafer second electrode 38.

If the laminated piezoelectric composite is to have a cover layer, seventh and eighth steps are performed before the stack is treated for bonding. Since the laminated piezoelectric composite may not have a cover layer in all implementations, the seventh and eighth steps are optional.

An optional seventh step illustrated in FIG. 9G and FIG. 10G involves applying (e.g., spraying) the plasticizing solvent over second adhesive carrier layer 100′, as depicted by arrows 42. The optional eighth step illustrated in FIG. 9H and FIG. 10H involves positioning a cover layer 48 over second adhesive carrier layer 100′. Preferably the cover layer 48 is a metallic conductor layer, such as aluminum, for example. In the illustrated embodiment, cover layer 48 has a thickness of about 0.05 mm. In embodiments in which cover layer 48 is utilized, preferably a ratio of thickness of cover layer 48 to substrate 20 is on the order of about 1:4, and a ratio of the elastic modules of cover layer 48 to substrate 20 is on the order of about 1:3.

Either after the sixth step, or after the optional seventh and eighth steps, the multilayer stack as thusly formed is treated under pressure and temperature to bond the layers into the laminated piezoelectric member. Preferably the multilayer stack is positioned in a fixture or the like which keeps the entire stack relative flat during the treatment process. In an example mode of fabrication, using a polyimide film as the adhesive carrier layers, the treatment occurs at a pressure of 75 kPa and a temperature of 215° C. During the treatment, the plasticizing solvent is driven off so that the polyimide film layers harden and serve to bond the constituent layers of the multilayer stack.

Again it is noted that the substrate 20 and the optional cover layer 48 are preferably chosen of materials which have a different coefficient of thermal expansion whereby, during cooling after the heat and pressure treating process and after removal from the fixture, the laminated piezoelectric member has a slightly domed configuration. During the heat and pressure treating process, the temperature is kept below a depoling temperature of the piezoelectric wafer.

Although various embodiments have been shown and described in detail, the claims are not limited to any particular embodiment or example. None of the above description should be read as implying that any particular element, step, range, or function is essential such that it must be included in the claims scope. The scope of patented subject matter is defined only by the claims. The extent of legal protection is defined by the words recited in the allowed claims and their equivalents. It is to be understood that the invention is not to be limited to the disclosed embodiment, but on the contrary, is intended to cover various modifications and equivalent arrangements.

What is claimed is:

1. A laminated piezoelectric composite comprising:
a metallic substrate;
a piezoelectric wafer having a first surface and a second surface;
a first adhesive carrier layer between the first surface of the piezoelectric wafer and the substrate, the first adhesive carrier layer serving both to adhere the first surface of the piezoelectric wafer to the substrate and to carry a first conductive lead for supplying an electrical signal or voltage to the first surface of the piezoelectric wafer;
a second conductive lead for supplying an electrical signal or voltage to the second surface of the piezoelectric wafer.

2. The apparatus of claim 1, wherein the first adhesive carrier layer comprises a high dielectric soluble aromatic polyimide film.

3. The apparatus of claim 1, wherein the first adhesive carrier layer comprises a plasticized film having the first conductive lead screened thereon with silver impregnated ink.

4. The apparatus of claim 1, wherein the first conductive lead comprises screened silver impregnated ink.

5. The apparatus of claim 1, wherein the first adhesive carrier layer has an appendage which extends in an extension direction beyond a footprint of the substrate for carrying the first conductive lead, the first adhesive carrier layer carrying the first conductive lead so that an end of the first conductive lead contacts a first electrode of the piezoelectric wafer.

6. The apparatus of claim 1, further comprising a second adhesive carrier layer which serves to carry the second conductive lead.

7. The apparatus of claim 6, further comprising a cover layer, and wherein the second adhesive carrier layer serves both to adhere the cover layer to the second surface of the piezoelectric wafer and to carry the second conductive lead.

8. The apparatus of claim 6, wherein the first adhesive carrier layer and the second adhesive carrier layer form a fused multilayer conductor carrier, and wherein in a thickness direction of the fused multilayer conductor carrier the first conductive lead does not overlap the second conductive lead.

9. The apparatus of claim 8, wherein each of the first adhesive carrier layer and the second adhesive carrier layer have an appendage which extends in an extension direction beyond a footprint of the substrate, wherein in the thickness direction the appendage of the first adhesive carrier layer at least partially covers the second conductive lead and the appendage of the second adhesive carrier layer at least partially covers the first conductive lead.

10. The apparatus of claim 9, wherein the appendage of the first adhesive carrier layer is configured to form a first relief and the appendage of the second adhesive carrier layer is configured to form a second relief, and wherein a distal end of the first conductor is exposed by the second relief and a distal end of the second conductor is exposed by the first relief.

11. A method of making a laminated piezoelectric composite, the laminated piezoelectric composite comprising at least a substrate and a piezoelectric wafer, the method comprising:
forming a first conductive lead on a first adhesive carrier layer;
inserting the first adhesive carrier layer between a first surface of the piezoelectric wafer and the substrate;
using the first adhesive carrier layer to adhere the first surface of the piezoelectric wafer to the substrate and to carry the first conductive lead for supplying an electrical signal or voltage to the first surface of the piezoelectric wafer; and
connecting a second conductive lead to a second surface of the piezoelectric wafer.

12. The method of claim 11, further comprising forming the first adhesive carrier layer to comprise a high dielectric soluble aromatic polyimide film.

13. The method of claim 11, further comprising forming the first conductive lead on the first adhesive carrier layer by screening with silver impregnated ink.

14. The method of claim 11, further comprising plasticizing the first adhesive carrier layer to adhere the first surface of the piezoelectric wafer to the substrate.

15. The method of claim 11, further comprising configuring the first adhesive carrier layer to have an appendage which extends in an extension direction beyond a footprint of the substrate for carrying the first conductive lead, the first adhesive carrier layer being configured to carry the first conductive lead so that an end of the first conductive lead contacts a first electrode of the piezoelectric wafer.

16. The method of claim 11, further comprising forming the second conductive lead on a second adhesive carrier layer and adhering the second adhesive carrier layer to the second surface of the piezoelectric wafer.

17. The method of claim 16, further comprising using the second adhesive carrier layer both to adhere the cover layer to the second surface of the piezoelectric wafer and to carry the second conductive lead.

18. The method of claim 16, further comprising fusing the first adhesive carrier layer and the second adhesive carrier layer to form a fused multilayer conductor carrier, and wherein in a thickness direction of the fused multilayer conductor carrier the first conductive lead does not overlap the second conductive lead.

19. The method of claim 18, wherein each of the first adhesive carrier layer and the second adhesive carrier layer have an appendage which extends in an extension direction beyond a footprint of the substrate, wherein in the thickness direction the appendage of the first adhesive carrier layer at least partially covers the second conductive lead and the appendage of the second adhesive carrier layer at least partially covers the first conductive lead.

20. The method of claim 19, further comprising configuring the appendage of the first adhesive carrier layer to form a first relief and configuring the appendage of the second adhesive carrier layer to form a second relief, and wherein a distal end of the first conductor is exposed by the second relief and a distal end of the second conductor is exposed by the first relief.

21. A laminated piezoelectric composite comprising:
a metallic substrate;
a piezoelectric wafer having a first surface and a second surface;
a first adhesive carrier layer between the first surface of the piezoelectric wafer and the substrate, the first adhesive carrier layer serving both to adhere the first surface of the piezoelectric wafer to the substrate and to carry a first conductive lead for supplying an electrical signal or voltage to the first surface of the piezoelectric wafer;
a second adhesive carrier layer adhered to the second surface of the piezoelectric wafer and carrying a second conductive lead for supplying an electrical signal or voltage to the second surface of the piezoelectric wafer;
wherein each of the first adhesive carrier layer and the second adhesive carrier layer have an appendage which extends in an extension direction beyond a footprint of the substrate, and wherein the appendage of the first adhesive carrier layer and the appendage of the second adhesive carrier layer form a fused multilayer conductor carrier, and wherein in a thickness direction of the fused multilayer conductor carrier the first conductive lead does not overlap the second conductive lead.

22. The apparatus of claim 21, wherein in the thickness direction the appendage of the first adhesive carrier layer at least partially covers the second conductive lead and the appendage of the second adhesive carrier layer at least partially covers the first conductive lead.

23. The apparatus of claim 22, wherein the appendage of the first adhesive carrier layer is configured to form a first relief and the appendage of the second adhesive carrier layer is configured to form a second relief, and wherein a distal end of the first conductor is exposed by the second relief and a distal end of the second conductor is exposed by the first relief.

24. The apparatus of claim 21, further comprising a cover layer, and wherein the second adhesive carrier layer serves both to adhere the cover layer to the second surface of the piezoelectric wafer and to carry the second conductive lead to the second surface of the piezoelectric wafer.
